(19) United States
(12) Patent Application Publication
(10) Pub. No.: US 2007/0095563 A1
(43) Pub. Date: May 3, 2007

(54) Circuit board having deformation interrupting section and circuit board forming method

(75) Inventor: Takanori Sekido, Hachioji-shi (JP)

Correspondence Address: Scully, Scott, Murphy & Presser, 400 Garden City Plaza, Garden City, NY, 11530-3319, US

(73) Assignee: OLYMPUS CORPORATION, Tokyo (JP)

(21) Appl. No.: 11/640,656

(22) Filed: Dec. 18, 2006

Related U.S. Application Data
(63) Continuation of application No. 10/784,631, filed on Feb. 23, 2004.

(30) Foreign Application Priority Data
Feb. 28, 2003 (JP) 2003-054172

(51) Int. Cl. H05K 1/09; H05K 1/03

(52) U.S. Cl. 174/256

(57) ABSTRACT

The invention provides a circuit board that includes a flat core plate, a buildup layer having insulation layers and conductor layers alternately stacked on each other, and surface conductor layers provided on the buildup layer. The circuit board further includes deformation-interrupting sections extending through the insulation layers between the conductor layers as electric wires. The deformation-interrupting sections adjust the thermal expansion coefficient of the whole circuit board, and enhance the rigidity of the circuit board. The invention also provides a method for forming the circuit board.

### CROSS-REFERENCE TO RELATED APPLICATIONS

This application is a continuation application of U.S. application Ser. No. 10/784,631 filed Feb. 23, 2004 which is, based upon and claims the benefit of priority from the prior Japanese Patent Application No. 2003-054172, filed Feb. 28, 2003, the entire contents of each of which are incorporated herein by reference.

### BACKGROUND OF THE INVENTION

1. Field of the Invention

The present invention relates to a circuit board in which deformation caused by an external load, such as bending or twisting, or an inner load, such as thermal stress due to a change in ambient temperature, is suppressed, and a method for forming the circuit board.

2. Description of the Related Art

In general, electronic devices contain a printed circuit board with a large number of electronic components mounted thereon, thereby providing various electric circuits. For example, FIG. 8 is a sectional view illustrating the conventional printed circuit board of a multilayer structure provided with an electronic component, disclosed in Jpn. Pat. Appln. KOKAI Publication No. 2000-216550.

In the printed circuit board, a multilayer structure, called a buildup layer, which is formed of inner conductor layers 32 and 33 and interlevel dielectric (interlevel insulator layers) 34 and 35, is generally provided on a flat core plate 31. The inner conductor layers 32 and 33 have blank portions 38, and surface conductor layers 39 as the uppermost layers that will be formed into electrode pads for mounting an electronic component 40.

The surface conductor layers 39 are electrically connected and mechanically bonded to the terminal electrodes 41 of the electronic component 40 by a conductive bonding material 36. Further, solder-resist 37 is provided which electrically isolates the surface conductor layers 39 as the electrode pads and protects portions of the outermost interlevel insulator layers 35 and surface conductor layers.

In the above structure, the blank portions 38 reduce the volume of the inner conductor layers 32 and 33 of a high thermal expansion coefficient, when the inner conductor layers 32 and 33 are thermally expanded because of a change in temperature, thereby reducing the adverse influence of the thermal expansion. In other words, the blank portions 38 make the thermal expansion coefficient of the entire printed circuit board close to that of the electronic component mounted on the board. Therefore, when an electronic components is mounted on the printed circuit board by a conductive bonding material, such as solder, the thermal stress that occurs due to the differences between the thermal expansion coefficients of the printed circuit board, electronic component and conductive bonding material is reduced. Thus, the blank portions 38 increase the resistance of the circuit board against changes in ambient temperature.

Jpn. Pat. Appln. KOKAI Publication No. 2000-216550 further discloses a structure in which buffer sections formed of a buffer material, such as silicone rubber, are employed instead of the blank portions 38. This publication yet further discloses a structure in which buffer layers formed of a buffer material are provided between the inner conductor layer and electrode pads.

As stated above, in the technique of Jpn. Pat. Appln. KOKAI Publication No. 2000-216550, the blank portions, buffer sections or buffer layers reduce the stress due to the differences in thermal expansion coefficient between the printed circuit board, electronic component and conductors, thereby enhancing the resistance against changes in ambient temperature.

### BRIEF SUMMARY OF THE INVENTION

According to an aspect of the invention, there is provided a circuit board comprising: a core plate; a buildup layer including insulation layers and conductor layers alternately stacked on each other; and a deformation-interrupting section extending through the insulation layers between the conductor layers in contact with the conductor layers, the deformation-interrupting section being formed of a material having a lower thermal expansion coefficient and a higher Young's modulus than the insulation layers, the deformation-interrupting section interrupting deformation of the insulation layers when there is a change in ambient temperature or an external force is applied to the circuit board. In the circuit board, the deformation-interrupting section is formed of an insulator or conductor.

According to another aspect of the invention, there is provided a method of forming a circuit board comprising: forming an interlevel insulator layers on a core plate; forming a hole through the interlevel insulator layers; filling the hole with an insulator or a conductor, thereby forming a deformation-interrupting section, the insulator or the conductor having a lower thermal expansion coefficient and a higher Young's modulus than the interlevel insulator layers; forming an inner conductor layer on the interlevel insulator layers with the deformation-interrupting section; forming a buildup layer having the interlevel insulator layers and the inner conductor layers are stacked upon each other; and forming the wire or the electrode on the buildup layer.

### BRIEF DESCRIPTION OF THE SEVERAL VIEWS OF THE DRAWING

FIG. 1 is a sectional view of a circuit board according to a first embodiment of the invention, illustrating a state in which an electronic component is mounted;

FIGS. 2A and 2B show examples of shapes of electrodes provided on the circuit board of the first embodiment;

FIG. 3 shows a solder bump formed on a terminal electrode of the circuit board of the first embodiment;

FIG. 4 is a sectional view of a circuit board according to a second embodiment of the invention, illustrating a state in which an electronic component is mounted;

FIGS. 5A and 5B are sectional views illustrating structure of the circuit boards prepared for proving that the invention has an effect of increasing the reliability of the boards;

FIGS. 6A and 6B are sectional views illustrating circuit boards, electronic components and their bonded portions, used for computing the degrees of their deformation due to bending force and heat applied thereto in finite element method simulations;

FIG. 6C is a list illustrating the properties of the members used in the finite element method simulations;

FIGS. 7A and 7B are views useful in explaining conditions for simulating the deformation for a circuit board due to bending force and heat applied thereto in the finite element method simulations; and

FIG. 8 is a sectional view illustrating a conventional printed circuit board of a multilayer structure provided with an electronic component.

### DETAILED DESCRIPTION OF THE INVENTION

Embodiments of the invention will be described in detail with reference to the accompanying drawings.

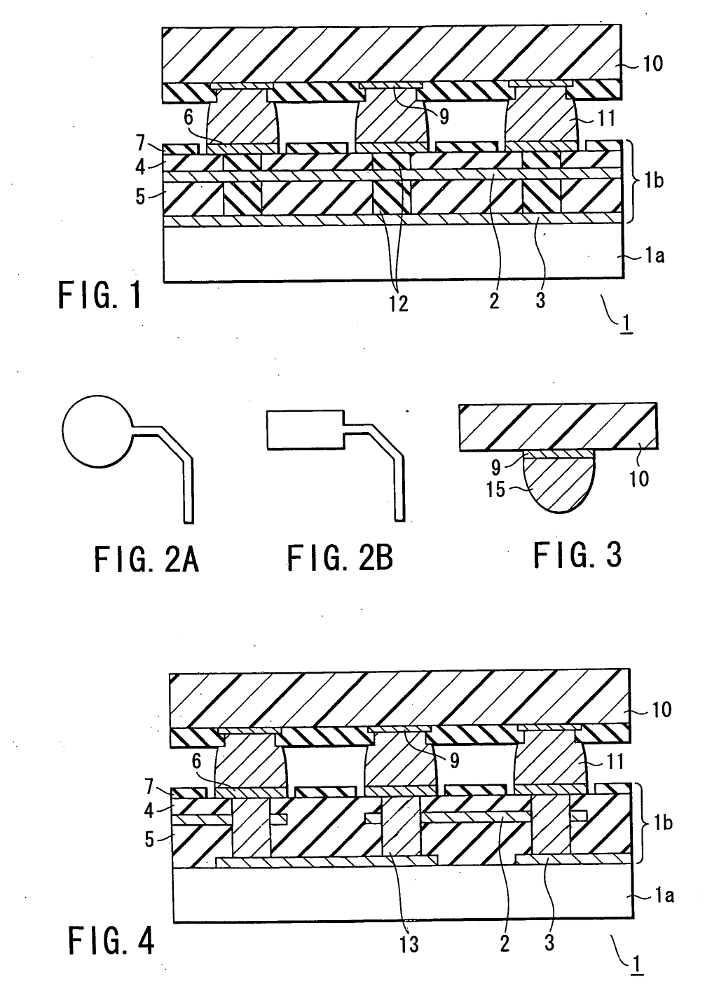

FIG. 1 is a sectional view illustrating a circuit board, such as a printed board, with an electronic component according to a first embodiment mounted thereon.

A circuit board 1 has a structure in which inner conductor layers 2 and 3 and interlevel insulator layers 4 and 5 are alternately stacked to form a buildup layer 1b on a core plate 1a , and surface conductor layers 6 are provided on the layer 1b . The surface conductor layers (terminal sections) 6 are electrically and mechanically connected, by a conductive bonding material 11, to the terminal electrodes 9 of an electronic component 10, such as a ball grid array (BGA) or chip scale (or size) package (CSP). This connection is performed using a so-called surface mounting technique. Of course, another conventional mounting technique using, for example, soldering of lead terminals may be employed as well as the surface mounting technique. A solder-resist layer 7 is provided around the surface conductor layers (terminal sections) 6.

The core plate 1a is, for example, an organic material plate represented by an FR-4 grade glass epoxy multilayer plate (thermal expansion coefficient: 10 ppm/° C.; Young's modulus: 20 GPa), or a ceramic plate, or a metal plate. The core plate 1a has a multilayer structure of, preferably, one to eight layers. The core plate 1a is a flat plate with a thickness of 0.05 to 0.5 mm. The properties of the core plate 1a vary between the above-mentioned materials. It is preferable that the thermal expansion coefficient is 5 to 15 ppm/° C., and the Young's modulus is 10 to 90 GPa.

The core plate 1a is located at the center of circuit board structure (FIG. 1 does not show the lower half), and the inner conductor layer 2 is provided on the core plate 1a by thermocompression bonding with an adhesive layer interposed or plating of a conductor. The conductor layers as electric wires in and on the core plate 1a impart a current and electrical signal conducting function to the board.

The inner conductor layers 2 and 3 of the buildup layer 1b are metal layers having a thickness of about 0.005 to 0.05 mm and formed of, for example, Cu, Ni, Mo, Al or Au. The inner conductor layers 2 and 3 are provided on the core plate 1a or interlevel insulator layers 4 and 5 by thermocompression bonding with an adhesive layer (not shown) interposed or plating. The properties of the inner conductor layers 2 and 3 vary between the above-mentioned materials. It is preferable that the thermal expansion coefficient is 5 to 30 ppm/° C., and the Young's modulus is 20 to 600 GPa. The typical material of the inner conductor layers 2 and 3 is non-electrolytic copper that has a thermal expansion coefficient of 17 ppm/° C. and a Young's modulus of 136 GPa. Further, the inner conductor layers 2 and 3 are formed, by etching or local deposition, as electric wires or as circular or rectangular electrodes as shown in FIGS. 2A and 2B. The inner conductor layers 2 and 3 have a function for transmitting currents or electrical signals through the circuit.

The interlevel insulator layers 4 and 5 are formed of an organic material to have a thickness of 0.005 mm or more. Interlevel insulator layers 4 and 5 are formed in contact with the inner conductor layers 2 and 3 and surface conductor layers 6, by thermocompression bonding, spin coating or curtain coating with adhesive layers (not shown) interposed therebetween. The adhesive layers themselves may serve as interlevel insulator layers. Preferably, the interlevel insulation layers 4 and 5 has a thermal expansion coefficient of 20 to 50 ppm/° C. and a Young's modulus of 0.5 to 20 GPa. The material of the interlevel insulation insulator layers 4 and 5 is, for example, fluorocarbon resin prepreg that has a thermal expansion coefficient of 17 ppm/° C. and a Young's modulus of 500 MPa. Further, epoxy resin prepreg, for example, is a material that has high bending strength. This material a thermal expansion coefficient of 15 ppm/° C. and has a Young's modulus of 16 GPa.

The interlevel insulator layers 4 and 5 serve to electrically isolate conductor layers represented by the inner conductor layers 2 and 3 and surface conductor layers 6. Further, the interlevel insulator layers 4 and 5 are adhesive therefore serve to bond the conductor layers.

The surface conductor layers 6 have a thickness of about 0.005 to 0.05 mm, and is formed of a metal, such as Cu, Ni, Mo, Al or Au. The surface conductor layers 6 are provided on the outermost interlevel insulator layers 4, by plating or thermocompression bonding with an adhesive layer (not shown) interposed therebetween. The properties of the surface conductor layers 6 vary between the above-mentioned materials. It is preferable that the thermal expansion coefficient is 5 to 30 ppm/° C., and the Young's modulus is 20 to 600 GPa. The typical material of the inner conductor layers 2 and 3 is non-electrolytic copper that has a thermal expansion coefficient of 17 ppm/° C. and a Young's modulus of 136 GPa. Further, the surface conductor layers 6 are formed, by etching or local deposition, as electric wires or as circular or rectangular electrodes (terminal sections) as shown in FIGS. 2A and 2B. The surface conductor layers 6 have a function for transmitting currents or electrical signals through the circuit. The surface conductor layers 6 are bonded to one surface of the conductive bonding material 11 that has the other surface bonded to the terminal electrodes 9. As a result, the layers 6 mechanically and electrically connect the electronic component 10 to the circuit board 1 via the conductive bonding material 11.

The solder-resist layer 7 of a uniform thickness (which falls within the range of 5 to 40 μm) is coated, by spin coating, curtain coating or deposition, on the interlevel insulator layers 4 and a part of surface conductor layers 6 that form the outermost portions of the circuit board 1. Preferably, the solder-resist 7 has a thermal expansion coefficient of 50 to 70 ppm/° C. and a Young's modulus of 5 to 10 GPa.

The solder-resist 7 serves to electrically isolate between the surface conductor layers (terminal sections) 6 in which electric wiring in formed, and also to protect the outer interlevel insulator layers 4 and surface conductor layers 6. The portions of the solder-resist 7 coated on the surface portions of the board 1 that are to be connected to the connecting portions of an external device, such as an electronic component, are removed to form holes therein. The diameters of the holes are determined based on those of the surface conductor layers 6 used as terminal electrodes, and are set to values different therefrom by −0.1 to +0.1 mm.

The terminal electrodes 9 of the electronic component 10 are provided on the surface of the electronic component that opposes the circuit board 1, by thermocompression bonding with an adhesive (not shown) interposed or plating. The electrodes 9 are formed of a metal, such as Cu, Ni, Mo, Al or Au, and have a thickness of 0.005 to 0.05 mm. The electrodes 9 are electrically and mechanically connected to the circuit board 1 via the conductive bonding material 11 described later in detail. The properties of the electrodes 9 vary between the above-mentioned materials. It is preferable that the thermal expansion coefficient is 5 to 30 ppm° C., and the Young's modulus is 20 to 600 GPa. The typical material of the electrodes 9 is non-electrolytic copper that has a thermal expansion coefficient of 17 ppm/° C. and a Young's modulus of 136 GPa.

Further, the terminal electrodes 9 of the electronic component 10 are formed, by etching or local deposition, as circular or rectangular electrodes as shown in FIGS. 2A and 2B. The electrodes 9 are bonded to the conductive bonding material 11 that is bonded to the surface conductor layers 6 on the printed circuit board. Thus, the electrodes 9 mechanically and electrically connect the electronic component 10 to the circuit board 1via the conductive bonding material 11.

The terminal electrodes 9 may be formed of conductor layers, or may have a solder bump 15 on the terminal electrodes 9 thereon as shown in FIG. 3. If a plurality of electronic components 10 are mounted on the circuit board 1, the electric components 10 and circuit board 1 cooperate to provide electric circuits having various functions. An epoxy resin is mainly used as the material of the package of the electronic component 10, but ceramic may be used as the material. The outer dimensions of the electronic component 10 vary between types or makers. However, the component 10 is generally in the shape of substantially a rectangular parallelepiped with one side of 3 to 50 mm and a thickness of 0.5 to 2 mm.

The conductive bonding material 11 is interposed between the surface conductor layers 6 of the circuit board 1 and terminal electrodes 9, thereby electrically and mechanically connecting the conductor layers 6 to the electrodes 9. The conductive bonding material 11 may be an electrically conductive material, such as solder, which provides a diffused junction between the conductor layers 6 and the electrodes 9 to electrically and mechanically connect them. On the other hand, the material 11 may be formed by mixing or distributing a conductive material into a non-conductive bonding material, such as an anisotropic conductive resin. In this case, the conductor layers 6 and electrodes 9 are electrically connected by the conductive material mixed or distributed in the non-conductive bonding material, while they are mechanically connected by hardening and contracting the non-conductive bonding material.

In the former case, the bonding material 11 is solder or lead-free solder, and its properties depend upon, for example, its composition. It is preferable that the fusing point is 130 to 320/° C., the thermal expansion coefficient is 10 to 30 ppm/° C., and the Young's modulus is 20 to 50 GPa. In the latter case, the properties depend upon the type of material. It is preferable that the thermal expansion coefficient is 50 to 200 ppm/° C., and the Young's modulus is 3 to 10 GPa. When the electronic component 10 is mounted onto the circuit board 1, the conductive bonding material 11 is supplied only to the surface conductor layers 6 by dispensing or screen printing.

After the electronic component 10 is mounted to the circuit board 1, the conductive bonding material 11 is in the shape of rods, each of which has upper and lower surfaces provided with the electrode 9 and surface conductor layer 6, respectively. Each rod has a thickness of 0.1 to 1 mm, and a diameter 0.5 to 2 times the diameter of the conductor layer 6 or electrode 9.

A description will now be given of insulative deformation-interrupting sections 12 by which the present invention is characterized.

As shown in FIG. 1, the insulative deformation-interrupting sections 12 vertically extend through the interlevel insulator layers 4 and 5, and have their upper and lower surfaces kept in contact with or bonded to the inner conductor layers 2 and 3 and surface conductor layer 6.

The insulative deformation-interrupting sections 12 are formed of a material having a lower thermal expansion coefficient and higher rigidity than the material of the interlevel insulator layers 4 and 5. The properties of the sections 12 slightly vary between materials used. It is preferable that the thermal expansion coefficient is 5 to 30 ppm/° C., and the Young's modulus is 50 to 400 GPa. The insulative deformation-interrupting sections 12 suppress deformation of the interlevel insulator layers 4 and 5 due to their thermal expansion. The insulative deformation-interrupting sections 12 are formed of, for example, a ceramic paste that preferably has a thermal expansion coefficient of 4 to 15 ppm/° C. and a Young's modulus of 200 to 400 GPa (the thermal expansion coefficient and Young's modulus vary between types of ceramic).

A description will be given of a method for forming the insulative deformation-interrupting sections 12, using, as examples, the layers 12 provided in contact with the inner conductor layer 3.

After the interlevel insulator layer 5 is formed on the inner conductor layer 3, portions of the interlevel insulator layer 5 are removed by applying a laser beam thereto or by an etching technique (wet etching, RIE, etc.). Alternatively, the interlevel insulator layers 5 is formed on the inner conductor layer 3, using a mask of, for example, a resin, thereby forming holes or grooves in the interlevel insulator layers 5. These holes or grooves are filled with an insulative deformation-interrupting material (in this embodiment, ceramic). The insulative deformation-interrupting material may be a resin of a low thermal expansion coefficient, which is identical to the resin used for the formation of the interlevel insulator layers 5. The thickness of the insulative deformation-interrupting section is, at maximum, equal to that of the interlevel insulator layers 4, and is shaped like a rod or bowl that has upper and lower surfaces kept in contact with the inner conductor layers 2 and 3 and surface conductor layers 6.

The function of the first embodiment will be described.

Assume that the temperature of the circuit board 1 in which the insulative deformation-interrupting sections 12 are formed has changed because of a change in ambient temperature, or the heat generated by the mounted component. At this time, the inner conductor layers 2 and 3, interlevel insulator layers 4 and 5, which provide the circuit board 1, and the electronic component 10 and conductive bonding material 11 expand or contract in accordance with their own thermal expansion coefficients.

In the case of general circuit boards, the interlevel insulator interlevel insulator layers 4 and 5 of the circuit board 1have a much higher thermal coefficient than those of the electronic component 10 and conductive bonding material 11. Because of the differences in the thermal expansion coefficients, thermal stress occurs in the circuit board 1, the junction of the terminal electrodes 9 and bonding material 11, and the junction of the surface conductor layers 6 and bonding material 11. Therefore, if there is a great change in temperature, a crack may occur in those junctions and it result in destruction.

On the other hand, in the circuit board 1 of the embodiment, if there is a change in the temperature of the circuit board 1 shown in FIG. 1, the insulative deformation-interrupting sections 12 having a lower thermal expansion coefficient than the interlevel insulator interlevel insulator layers 4 and 5 interrupt the deformation of the interlevel insulator layers 4 and 5. As a result, the degree of deformation of the whole circuit board 1 is reduced. In other words, the thermal expansion coefficient of the whole circuit board 1 is made close to that of the electronic component 10 mounted on the circuit board 1.

Further, when the circuit board 1 is screwed to the housing of an electronic device, and a bending load is applied to the board 1, the buildup layer 1b (the inner conductor layers 2 and 3 and interlevel insulator layers 4 and 5) and surface conductor layers 6 of the board 1, and the electronic component 10 and conductive bonding material 11 show respective bending states based on their moduli of elasticity.

Interlevel insulator layers and a resin layer, such as a solder-resist layer, which occupy a large part of a general circuit board, generally have a low rigidity and easily deform if, for example, an external bending force is applied thereto. If an excessive bending force is applied to the circuit board, cracks may occur in inner conductor layers, or surface conductor layers connected to an electronic component via a conductive bonding material may peel off.

On the other hand, in the circuit board 1 of the invention, if an external bending force is applied thereto, the insulative deformation-interrupting sections 12 having a high young's modulus than the material of the interlevel insulator layers 4 and 5 interrupt the deformation of the interlevel insulator layers 4 and 5. As a result, the degree of deformation of the whole circuit board 1 due to the external force is reduced, which means that the rigidity of the whole circuit board is enhanced.

In the circuit board 1 of the embodiment, if the interlevel insulator layers having a high thermal expansion coefficient is deformed due to a change in temperature, the insulative deformation-interrupting sections (made of, for example, ceramic) having a lower thermal expansion coefficient than the interlevel insulator layers interrupt the deformation of the interlevel insulator layers. As a result, the degree of deformation of the whole circuit board is reduced. In other words, the thermal expansion coefficient of the whole circuit board is made close to that of the electronic component mounted thereon.

In addition, if bending stress occurs in the circuit board of the embodiment, the insulative deformation-interrupting sections that are provided in the interlevel insulator layers and have a higher rigidity than them reduces the degree of deformation due to the bending stress. This means that the rigidity of the whole circuit board is enchanced.

As described above, the embodiment provides a circuit board that is highly reliable even under changes in temperature, and shows a high resistance against external deforming (bending) forces.

A circuit board according to a second embodiment will be described.

FIG. 4 is a sectional view illustrating a circuit board, such as a printed circuit board, according to the second embodiment, which is provided with an electronic component mounted thereon. In FIG. 4, elements similar to those employed in the first embodiment (shown in FIG. 1) are denoted by corresponding reference numerals, and no detailed description is given thereof.

As shown, the circuit board 1 has a structure (buildup layer 1b ) in which inner conductor layers 2 and 3 and interlevel insulator layers 4 and 5 are alternately stacked on a core plate 1a , and surface conductor layers 6 provided on the top of the structure. An electronic component 10 is mounted on the circuit board 1 by connecting the surface conductor layers 6 to the terminal electrodes 9 of the component 10 via a conductive bonding material 11. In the above-described first embodiment, the insulative deformation-interrupting sections 12 are provided in the buildup layer 1b , while in the second embodiment, conductive deformation-interrupting sections 13 are provided in the buildup layer 1b.

Like the insulative deformation-interrupting sections 12, the conductive deformation-interrupting sections 13 are kept in contact with the interlevel insulator layers 4 and 5, inner conductor layers 2 and 3 and surface conductor layers 6. Further, the conductive deformation-interrupting sections 13 suppress deformation of the interlevel insulator layers 4 and 5 due to their thermal expansion, and electrically connect the inner conductor layers 2 and 3 and surface conductor layers 6.

The conductive deformation-interrupting sections 13 are formed of, for example, a conductive material, such as Sn—Pb alloy solder or lead-free solder. The properties of the sections 13 depend upon the composition of the alloy used. It is preferable that the fusing point is 130 to 320° C., the thermal expansion coefficient is 10 to 30 ppm° C., and the Young's modulus is 20 to 500 GPa. Mo (molybdenum) paste or W (tungsten) paste is typically used as the material of the sections 13. Mo paste has a thermal expansion coefficient of 5 ppm/° C. and a Young's modulus of 327 GPa, while W paste has a thermal expansion coefficient of 4.5 ppm/° C. and a Young's modulus of 400 GPa.

A description will be given of a method for forming the conductive deformation-interrupting sections 13, using, as examples, the conductive deformation-interrupting sections 13 provided in contact with the layer 1a of the upper part of a core board.

After the interlevel insulator layers 5 is formed on the inner conductor layer 3, portions of the interlevel insulator layers 5 are removed by applying a laser beam thereto or by an etching technique (wet etching, RIE, etc.). Alternatively, the interlevel insulator layers 5 is formed on the inner conductor layer 3, using a mask of, for example, thereby forming holes or grooves in the interlevel insulator layers 5. These holes or grooves are filled with solder paste. The resultant structure is heated to form the conductive deformation-interrupting sections 13.

Since the conductive deformation-interrupting sections 13 are formed of a conductive material, they can also be formed in a different manner. That is, after the inner conductor layer 2 is formed on the interlevel insulator layers 5, through holes that reach the inner conductor layer 3 are formed into the inner conductor layer 2 and interlevel insulator layers 5 by a laser beam or drill, thereby removing the portions corresponding to the deformation-interrupting sections 13. These holes are filled with paste solder, and the resultant structure is heated. Since this method does not need the solder-resist forming/removing process employed for forming the interlevel insulator layers, the cost and tact time required for producing the circuit board can be reduced. The structure other than the above is similar to that of the first embodiment, therefore is not described.

As described above, in the second embodiment, the conductive deformation-interrupting sections can make the thermal expansion coefficient of the whole circuit board close to that of the electronic component mounted thereon, and can enhance the rigidity of the whole circuit board, as in the first embodiment.

Accordingly, even after the electronic component is mounted, deformation of the circuit board due to their thermal expansion caused by a change in ambient temperature or the heat generated by the electronic component can be suppressed to thereby prevent breakage of the whole device. Further, the increase of the rigidity further reduces the influence of the External force. As a result, the whole device is made highly reliable. Furthermore, the use of a conductive material to form the deformation-interrupting sections enables the sections to be used as electric wires for electrically connecting the conductor layers, while keeping the function of the sections similar to that of the insulative deformation-interrupting sections employed in the first embodiment. This being so, high-density circuit can be designed easily, therefore a compact circuit device can be realized.

A description will be given of the measurements and simulations performed to prove the function and advantage of the circuit boards according to the first and second embodiments.

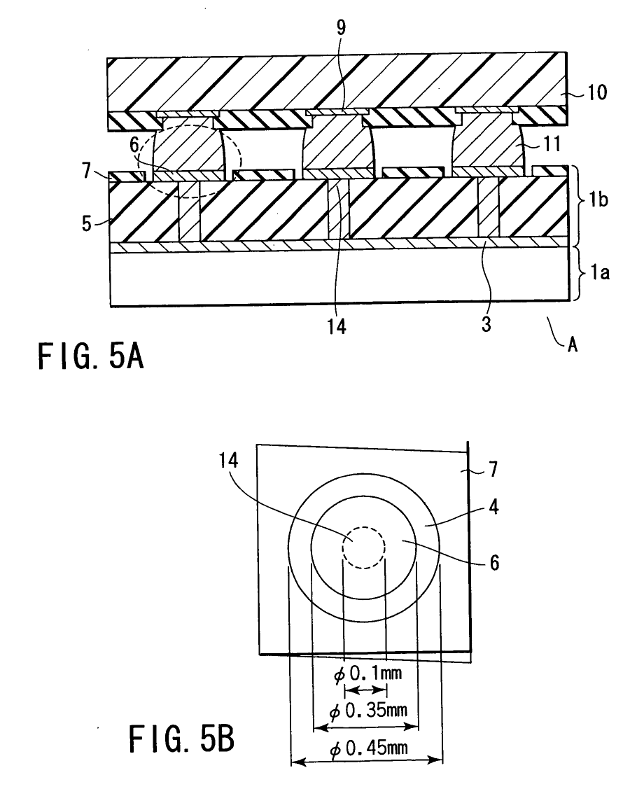

FIG. 5A is a sectional view illustrating a printed circuit board sample A formed for measurements that has a conductive deformation-interrupting sections extending through an insulation layer to an inner conductor layer. FIG. 5B is a view illustrating the dimensions and shapes of a terminal electrode and conductive deformation-interrupting section (cylindrical Cu layer) incorporated in the portion enclosed by the broken line in FIG. 5A.

The circuit board sample A comprises a core plate 1a, a buildup layer 1b provided on the core plate 1a and having an inner conductor layer 3 and interlevel insulator layers 5 stacked thereon, and surface conductor layers 6 provided on the buildup layer 1b . In the four-layer printed circuit board, cylindrical Cu layers 14 with a diameter φ of 0.1 mm, which serve as conductive deformation-interrupting sections, are provided in the interlevel insulator layers 5. The cylindrical Cu layers 14 extend through the interlevel insulator layers 5 from the lower surfaces of the surface conductor layers 6 to the upper surface of the inner conductor layer 3.

The surface conductor layers 6 as terminal electrodes bonded to a conductive bonding material 11 has a circular cross section with a diameter φ of 0.35 mm, and circular holes having a diameter φ of 0.45 mm are formed in a solder-resist 7. A CSP with a pitch of 0.65 mm is mounted as an electrode component 10 on the circuit board sample A. Sn—Pb eutectic solder is used as the conductive bonding material 11. Since the circuit board sample A was prepared for measurements for proving the advantages, the illustrated dimensions of each structural element are just examples, and are not always equal to those of an actual printed circuit board.

Circuit board samples identical to the above sample A and comparative circuit board samples B with no conductive deformation-interrupting section (cylindrical Cu layer 14 ) were subjected to a −40/125° C. temperature cycle test (the test was repeated just a thousand times). Table 1 shows the results of the test.

TABLE 1

| | | | Number of | Rate of |
|---|---|---|---|---|
| | | | occasions | occasions |
| | Sample No. | Test results | of failure | of failure |
| With conductive | 1 | Success in 1000 cycles | 0/3 | 0% |
| deformation-interrupting | 2 | Success in 1000 cycles | | |
| sections | 3 | Success in 1000 cycles | | |
| Without conductive | 1 | Success in 1000 cycles | 1/3 | 33% |
| deformation-interrupting | 2 | Failure in 817 cycles | | |
| sections | 3 | Success in 1000 cycles | | |

As is evident from table 1, all circuit board samples A (with the conductive deformation-interrupting sections) were succeeded in the test, while some of the circuit board samples B (without the conductive deformation-interrupting sections) were found to be defective. From this, it is confirmed that the conductive deformation-interrupting sections provided in the interlevel insulator layers 5 enhance the resistance of the circuit board against changes in temperature.

A description will now be given of the bending degrees and thermal deformation degrees of circuit boards resulting from finite element method simulations.

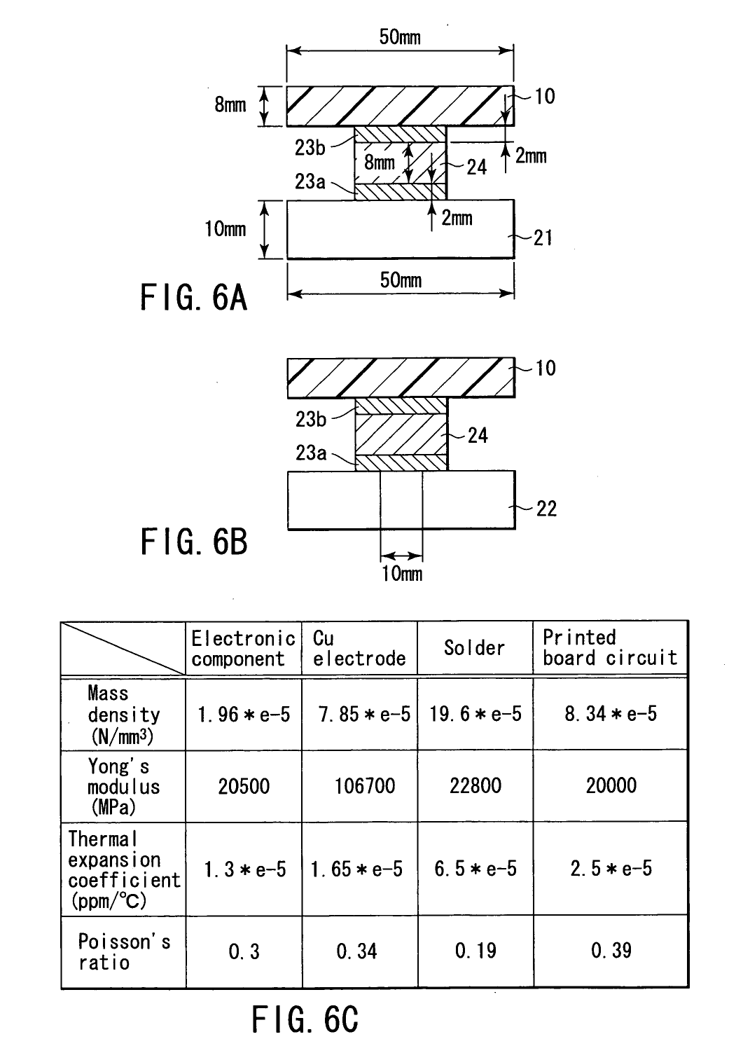

FIG. 6A shows the dimensions of a circuit board 21 without a deformation-interrupting section, while FIG. 6B shows the dimensions of a circuit board 22 with a deformation-interrupting section. FIG. 6C shows the values of the properties of the circuit boards. In each of the circuit boards 21 and 22, a Cu electrode 23a is electrically and mechanically connected to the Cu electrode 23b of an electronic component 10. In other words, the electronic component 10 is mounted on the circuit board. Since the circuit board samples shown in FIGS. 6A and 6b are assumed for proving the advantages, the illustrated dimensions of each structural element are just examples, and are not always equal to those of actual printed circuit boards.

1) Circuit board bending simulation

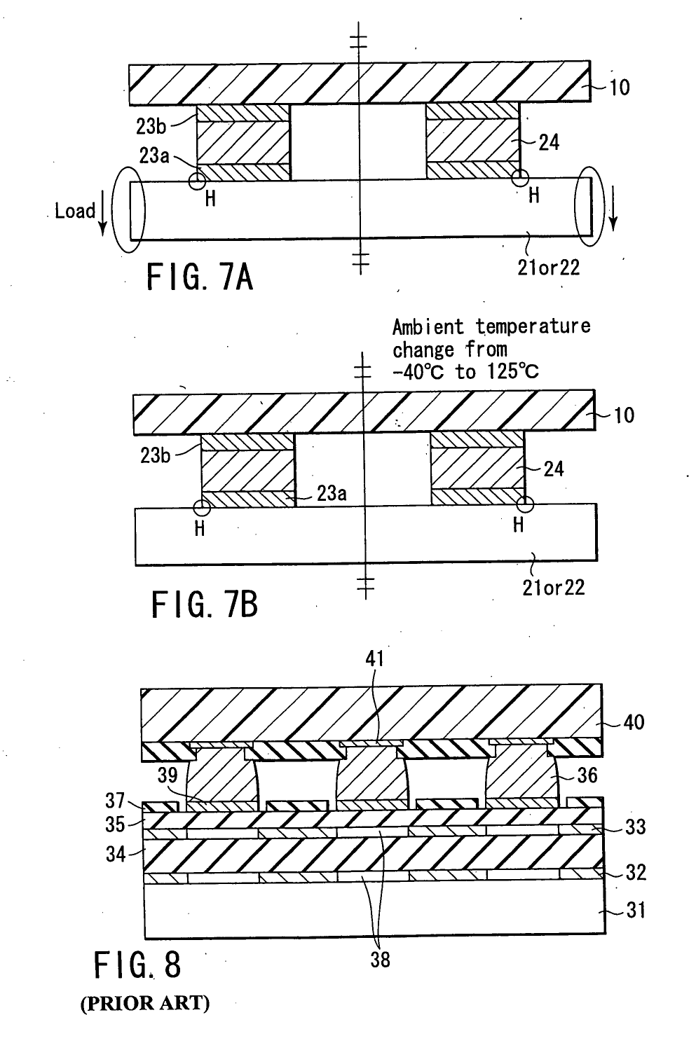

It was assumed that the center portions of the circuit boards 21 and 22, assuming which the right and left parts are symmetrical, were fixed as shown in FIG. 7A. It was also assumed that downward bending forces of 100 N were applied to the opposite sides of each circuit board. The calculation of the bending force exerted on one side of each circuit board was measured.

From the simulation, it was found that a maximum stress of 65.694 Pa occurred in the circuit board 21 having no deformation-interrupting section, and a maximum stress of 60.657 Pa occurred in the circuit board 22 having the deformation-interrupting section. The maximum stress occurred at point H of each junction in FIG. 7A.

From these results, it can be easily estimated that the deformation-interrupting section can reduce the bending stress occurring in the circuit board, therefore the circuit board can have a higher resistance of bending strength than conventional circuit boards.

2) Thermal stress simulation

It was assumed that the center portions of the circuit boards 21 and 22, assuming which the right and left parts are symmetrical, were fixed as shown in FIG. 7B. It was also assumed that the temperature around the mounted electronic component, conductive bonding material and circuit board was changed from −40° C. to 125° C. Under these simulation conditions, the maximum stress occurring at point H of each circuit board was computed.

From the simulation, it was found that a maximum thermal stress of 968.15 Pa occurred in the circuit board 21 having no deformation-interrupting section, and a maximum thermal stress of 526.35 Pa occurred in the circuit board 22 having the deformation-interrupting section. From these results, it can be easily estimated that the deformation-interrupting section can reduce the thermal stress occurring in the circuit board, therefore the circuit board can have a better thermal stress characteristic than conventional circuit boards.

In the simulations, part (point H) of a junction is extracted, and the stress reduction effect of the deformation-interrupting section at the extracted portion is computed. Actually, however, the stress reduction effect increases as the number of deformation-interrupting sections increases. If several hundreds to several thousands of deformation-interrupting sections are provided in a circuit board, it is easily expected that a large stress reduction effect can be obtained from all the deformation-interrupting sections.

Further, when an external load, such as a bending force or a change in temperature, is exerted upon a circuit board, if the stress occurring in the board is small, the effect of the load on the circuit board itself, the electronic component mounted thereon and their junctions is small. The smaller the effect of the load, the longer the life of each component of the device. It is easy to estimated that the deformation-interrupting sections employed in the circuit board in each embodiment prevent the junctions from being damaged, i.e., elongate the life of the circuit board and the component mounted thereon.

As described above, in the circuit board of the invention in which inner conductor layers and interlevel insulator layers are alternately stacked on each other on a core plate, deformation-interrupting sections having a lower thermal expansion coefficient and higher modulus of elasticity than the interlevel insulator layers are provided in the interlevel insulator layers. Therefore, even if the interlevel insulator layers having a high thermal expansion coefficient deform due to, for example, a change in ambient temperature, the deformation-interrupting sections having a lower thermal expansion coefficient interrupt the deformation of the interlevel insulator layers. As a result, the thermal expansion coefficient of the whole circuit board can be made close to that of the electronic component mounted thereon, and the rigidity of the whole circuit board against an external force, such as a bending force, can be enhanced.

Thus, the invention can provide a circuit board that has an enhanced thermal stress characteristic and high bending strength, i.e., that does not easily become defective even if a bending force is applied thereto or the ambient temperature is changed. In addition, if the deformation-interrupting sections are formed of a conductive material, they can be used as electric wires. This facilitates the design of high-density circuit and hence provides the formation of a high-density, compact circuit board.

The circuit board of the invention can be used not only as a circuit board of a one-sided multilayer structure, but also as a circuit board of a double-sided multilayer structure. Further, the circuit board of the invention has a multilayer structure in which interlevel insulator layers and inner conductor layers are stacked. The circuit board of the invention is used as a multilayer printed circuit board patterned by a laser beam, film-forming/etching and/or printing.

As described above in detail, the invention provides a circuit board with deformation-interrupting sections that impart an enhanced thermal stress characteristic and bending strength to the board, and that enables high-density circuit, and a method for forming the circuit board.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A circuit board comprising:
a core plate;
a buildup layer including insulation layers and conductor layers alternately stacked on each other; and
a deformation-interrupting section extending through the insulation layers between the conductor layers in contact with the conductor layers, the deformation-interrupting section being formed of a material having a lower thermal expansion coefficient and a higher Young's modulus than the insulation layers, the deformation-interrupting section interrupting deformation of the insulation layers when there is a change in ambient temperature or an external force is applied to the circuit board.

2. The circuit board according to claim 1, wherein the deformation-interrupting section is formed of a conductor.

3. The circuit board according to claim 2, wherein the conductor is formed of a material selected from the group consisting of Sn—Pb alloy solder, lead-free solder, Mo paste and W paste.

4. The circuit board according to claim 1, further comprising a second conductor layer, wherein the deformation-interrupting section extends through the second conductor layer.

5. The circuit board according to claim 4, further comprising a second insulation layer, wherein the deformation-interrupting section continuously extends through the first and second insulation layers.

6. The circuit board according to claim 5, wherein the deformation-interrupting section being formed of a material having a lower thermal expansion coefficient and a higher Young's modulus than the first and second insulation layers, the deformation-interrupting section interrupting deformation of the first and second insulation layers when there is a change in ambient temperature or an external force is applied to the circuit board.
